(19) United States
(12) Patent Application Publication
(10) Pub. No.: US 2010/0288553 A1
(43) Pub. Date: Nov. 18, 2010

(54) COOLING PAD CAPABLE OF ABSORBING ELECTROMAGNETIC INTERFERENCE

(75) Inventor: WEN-KAI CHIANG, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/540,348

(22) Filed: Aug. 12, 2009

(30) Foreign Application Priority Data
May 14, 2009 (CN) 200910302312.7

(51) Int. Cl. H05K 9/00

(52) U.S. Cl. 174/388

(57) ABSTRACT

A cooling pad capable of absorbing electromagnetic interference (EMI) is used to be connected between a cooling device and an electronic component. The cooling pad conducts heat generated by the electronic component to the cooling device, thereby to cool the electronic component. The cooling pad includes an EMI absorbing net made of electromagnetic absorbing material. Therefore, the cooling pad is capable of absorbing EMI generated by the electronic component.

### BACKGROUND

1. Technical Field

The present disclosure relates to cooling pads, and particularly to a cooling pad that can absorb electromagnetic interference (EMI).

2. Description of Related Art

With the development of electronic technology, electronic components are operating at ever higher frequencies. Consequently, more heat is being generated by the higher frequency electronic components. Cooling devices composed of copper or aluminum are usually used to cool such electronic components, where thermal conducting material is filled between the cooling devices and the electronic components for improving thermal conductive performance.

Additionally, a higher frequency electronic component also generates more electromagnetic interference (EMI) which can interfere with other electronic components by way of radiation or conduction. An EMI shield is used to shield EMI generated by the electronic component. However, if the electronic component is shielded with the EMI shield, effectiveness of the cooling device is sacrificed.

### BRIEF DESCRIPTION OF THE DRAWINGS

FIG. 1 is a sketch view of an exemplary embodiment of a cooling pad capable of absorbing EMI, a cooling device, and an electronic component.

FIG. 2 is a cutaway view of an exemplary embodiment of the cooling pad of FIG. 1.

FIG. 3 is a sketch view of an exemplary embodiment of an EMI absorbing net in the cooling pad of FIG. 1.

### DETAILED DESCRIPTION

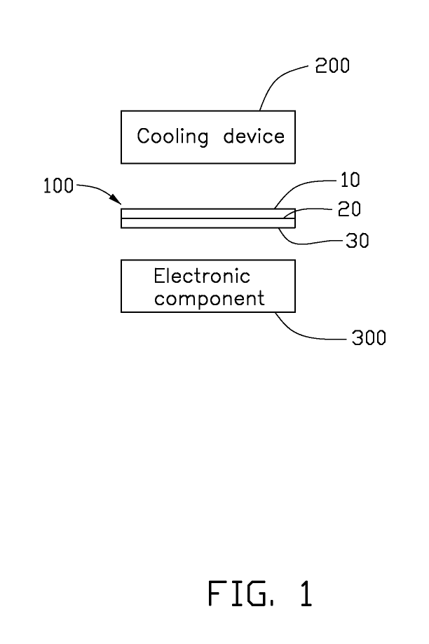

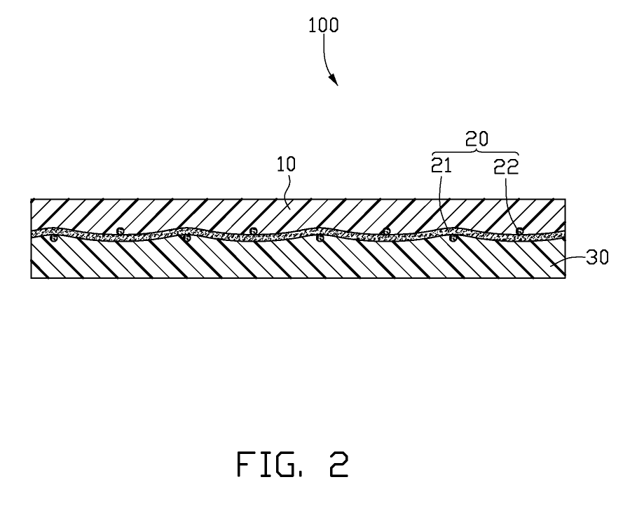

Referring to FIG. 1 and FIG. 2, an exemplary embodiment of a cooling pad 100 capable of absorbing electromagnetic interference (EMI) includes a first cooling layer 10, an EMI absorbing net 20, and a second cooling layer 30. The EMI absorbing net 20 is sandwiched between the first cooling layer 10 and the second cooling layer 30.

The first cooling layer 10 and the second cooling layer 30 are both made of silicone heat sink paste and are each about 0.6 millimeters (mm) thick, in one exemplary embodiment. Because silicone in the silicone heat sink paste has high compressibility and viscidity, the first cooling layer 10 is used to connect to a cooling device 200, and the second cooling layer 30 is used to connect to an electronic component 300. The EMI absorbing net 20 is about 0.5 mm thick, in one embodiment, and made of electromagnetic absorbing material which can absorb electrical and magnetic waves.

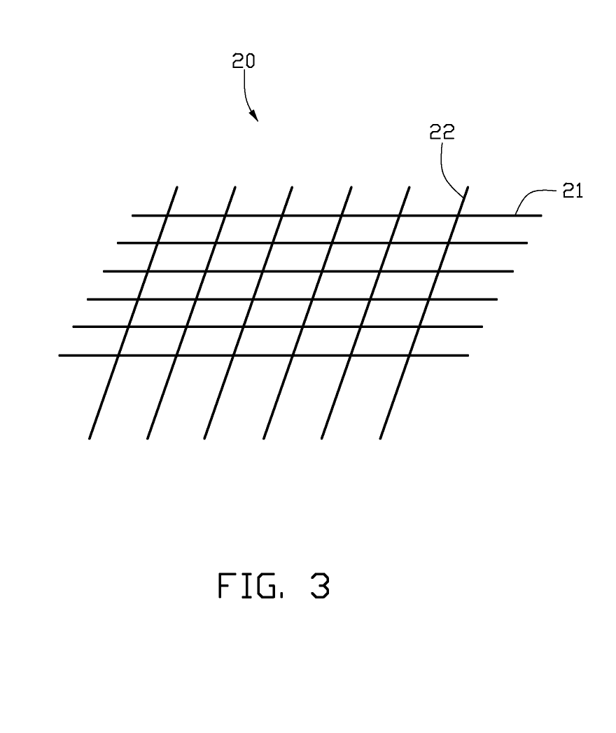

Referring to FIG. 3, the EMI absorbing net 20 includes a plurality of woofs 21 and a plurality of warps 22 crosswise with the plurality of woofs 21. Each of the plurality of woofs 21 and the plurality of warps 22 is a filament about 0.05 mm thick, in one embodiment, made of EMI absorbing nanoscale fiber via nano technology. A width between every two adjacent woofs 21 is about 0.1 mm. A width between every two adjacent warps 22 is about 0.1 mm. It may be understood that the values mentioned above may be changed depending on the embodiment.

The first cooling layer 10, the EMI absorbing net 20, and the second cooling layer 30 are compressed together when the cooling pad 100 is manufactured. The first cooling layer 10 and the second cooling layer 30 are contacted via net holes of the EMI net 20 and pasted together. Heat generated by the electronic component 300 is conducted to the cooling device 200 via the first cooling layer 10 and the second cooling layer 30 of the cooling pad 100, and EMI generated by the electronic component 300 is absorbed by the EMI absorbing net 20 of the cooling pad 100.

In one exemplary embodiment, a thickness of the cooling pad 100 is about 1.25 mm. In another exemplary embodiment, the thickness of the cooling pad 100 ranges from about 1.05 mm to about 2.08 mm. A thickness of each of the first cooling layer 10 and the second cooling layer 30 ranges from about 0.5 mm to about 1 mm. A thickness of the EMI absorbing net 20 ranges from about 0.05 mm to about 0.08 mm. A diameter of each of the plurality of woofs 21 and the plurality of warps 22 ranges from about 0.05 mm to about 0.08 mm. The net holes of the EMI absorbing net 20 may be another kind of hole shape, such as a comb shape.

It is to be understood, however, that even though numerous characteristics and advantages of the present disclosure have been set forth in the foregoing description, together with details of the structure and function of the disclosure, the disclosure is illustrative only, and changes may be made in details, especially in matters of shape, size, and arrangement of parts within the principles of the disclosure to the full extent indicated by the broad general meaning of the terms in which the appended claims are expressed.

What is claimed is:

1. A cooling pad capable of absorbing electromagnetic interference (EMI), the cooling pad comprising:
a first cooling layer made of silicone heat sink paste, to be connected to an electronic component to conduct heat generated by the electronic component;
a second cooling layer made of silicone heat sink paste, to be connected to a cooling device to transfer the heat to the cooling device; and
an EMI absorbing net made of electromagnetic absorbing material, and sandwiched between the first cooling layer and the second cooling layer for absorbing EMI generated by the electronic component.

2. The cooling pad of claim 1, wherein a thickness of each of the first cooling layer and the second cooling layer ranges from about 0.5 millimeters (mm) to about 1 mm.

3. The cooling pad of claim 1, wherein a thickness of the EMI absorbing net ranges from about 0.05 mm to about 0.08 mm.

4. The cooling pad of claim 1, wherein a thickness of the cooling pad ranges from about 1.05 mm to about 2.08 mm.

5. The cooling pad of claim 1, wherein the EMI absorbing net comprises a plurality of woofs and a plurality of warps crosswise with the plurality of woofs; the plurality of woofs and the plurality of warps are filaments made of EMI absorbing nanoscale fiber via nano technology.

6. The cooling pad of claim 5, wherein a diameter of each of the plurality of woofs and the plurality of warps ranges from about 0.05 millimeters to 0.08 millimeters.

7. The cooling pad of claim 5, wherein a width between every two adjacent woofs is about 0.1 millimeters.

8. The cooling pad of claim 5, wherein a width between every two adjacent warps is about 0.1 millimeters.
